(19) United States
(12) Patent Application Publication
(10) Pub. No.: US 2011/0014368 A1
(43) Pub. Date: Jan. 20, 2011

(54) Carbon nanotube growth at reduced temperature via catalytic oxidation

(75) Inventor: Aleksey V. Vasenkov, Huntsville, AL (US)

Correspondence Address: TOMAS FRIEND, LLC, 886 Indian Rock Road, Lebanon Church, VA, 22641, US

(73) Assignee: CFD RESEARCH CORPORATION, Huntsville, AL (US)

(21) Appl. No.: 12/502,745

(22) Filed: Jul. 14, 2009

(51) Int. Cl. B05D 7/24; C23C 16/26

(52) U.S. Cl. 427/180; 427/249.1; 977/742; 977/773

(57) ABSTRACT

The growth temperature of carbon nanotubes on a catalyst distributed on a substrate is reduced by controlling graphene layer formation on the catalyst and catalyst deactivation by catalytic oxidation.

### CROSS-REFERENCE TO RELATED APPLICATIONS

This application claims priority under 35 U.S.C. 120 to application Ser. No. 11/668,741 filed 30 Jan. 2007 and which is incorporated herein by reference in its entirety.

### STATEMENT REGARDING FEDERALLY SPONSORED RESEARCH OR DEVELOPMENT

The U.S. Government may have certain rights in this invention pursuant to SBIR Contract No.: 0724878 awarded by the National Science Foundation.

### BACKGROUND OF THE INVENTION

1. Field of the Invention

The present invention relates to methods and systems for synthesizing carbon nanotubes (CNTs) and, in particularly, to reducing the temperature for CNT growth by supplying hydrocarbon-containing gas and oxygen-containing gas simultaneously during CNT formation.

2. Description of Related Art

Carbon nanotubes (CNTs) are graphitic filaments/whiskers with diameters ranging from 0.4 to 500 nm and with lengths in the range of several micrometers to centimeters. CNTs have the potential to play a central role in nanotechnology due to their molecular scale electronic and mechanical properties. For example, CNTs revealed remarkable field-emission characteristics, excellent mechanical and electrical properties, and chemical stabilities. Laser ablation and arc discharge synthesis are efficient in fabricating nanotube materials in large quantities. In Chemical Vapor Deposition processes, carbon-containing gaseous feedstock is heated to a temperature in excess of 700° C. and delivered to a substrate where a catalytic metal layer promotes the growth of CNTs. Plasma-enhanced Chemical Vapor Deposition provides the additional advantage of controlling the location, alignment, and diameter of free-standing CNTs.

The standard temperature for the direct growth of CNTs on a substrate is about 700° C., which is a limitation to designers who seek to create CNT-based devices and materials. If the growth temperature can be reduced to 600° C. without deteriorating CNT properties, the spectrum of applications for CNTs grown in situ can be substantially widened. For example, the synthesis of CNTs at 600° C. enables the direct deposition of CNTs on aluminum electrodes, which have a melting point of 660° C., for cost-efficient fabrication of ultracapacitors. Ultracapacitors utilizing carbon nanotubes have a potential to provide more power, increased energy density and longer life than traditional batteries and capacitors that store electrical energy.

Methods for reducing the temperature of CNT synthesis via plasma-assisted deposition process have been reported. In these methods, the energy necessary for CNT growth is provided by plasma rather than by an external heating source. Although results of these studies are encouraging, deterministic growth of well-graphitized CNTs at substrate temperatures below 700° C. has not yet been demonstrated. A method for low-temperature growth of CNTs by selectively heating metallic catalytic nanoparticles is disclosed in U.S. application Ser. No. 11/668,741 filed 30 Jan. 2007.

### BRIEF SUMMARY OF THE INVENTION

In one embodiment, the present invention is a method for synthesizing CNTs on a conducting or non-conducting substrate comprising controlling graphene layer formation and catalyst deactivation via catalytic oxidation.

In a second embodiment, the present invention is an article of manufacture comprising CNTs synthesized on a conducting or non-conducting substrate wherein the substrate cannot withstand temperatures in excess of 600° C.

In a third embodiment, the present invention is a method for reducing the growth temperature of CNT synthesis without deteriorating CNT structure comprising controlling graphene layer formation and catalyst deactivation via catalytic oxidation.

In a fourth embodiment, the present invention is an article of manufacture comprising CNTs synthesized at reduced temperature.

### BRIEF DESCRIPTION OF THE DRAWINGS

FIG. 1 is a magnified image of CNTs grown at 700° C., without catalytic oxidation.

FIG. 2 is a magnified image of CNTs grown at 700° C. with catalytic oxidation

FIG. 3 is a magnified image of CNTs grown at 600° C. without catalytic oxidation.

FIG. 4 is a magnified image of CNTs grown at 600° C. with catalytic oxidation.

### DETAILED DESCRIPTION OF THE INVENTION

Definitions:

The term “carbon nanotubes” (CNTs) is used herein in a generic sense to include single-walled and multi-walled carbon nanotubes, carbon nanofibers, carbon nanofilaments, and carbon nanoropes.

The term “catalyst” is used with the art accepted meaning and, in the case of catalytic CNT synthesis includes metals such as Ni, Fe, Co, Cu, Al, V, Y, Mo, Pt, Pd and their binary and ternary alloys. A catalyst may be sputter deposited in thin films on substrates and exist as nanoparticles.

Reducing CNT Growth Temperature Via Catalytic Oxidation

The growth of CNTs can be separated into two major processes: delivery of a carbon supply to a growing wall, and self-assembly of carbon into CNTs. It is well established that delivery of carbon typically occurs via catalytic decomposition of hydrocarbons on the surface of a catalyst. The present inventors have demonstrated that this catalytic decomposition is not temperature dependent. Because carbon incorporation into CNTs has a very high energy barrier, if during CNT synthesis the growth temperature drops below 700° C., the rate of carbon incorporation into CNT decreases while the rate of carbon production due to hydrocarbon decomposition remains practically the same. The end result is the formation of a graphene layer on the top of the catalyst and catalyst deactivation, which prohibits the growth of CNTs.

The growth of CNTs on iron based AL250-R62807 catalyst with and without simultaneous supply of oxygen at 600° C. and 700° C. were compared. Unexpectedly CNTs grown at 600° C. in the presence of oxygen are of higher quality and are produced with a yield approximately half that of growth without oxygen. At 700° C., the yield with oxygen is about 80% of the yield without oxygen, with comparable CNT quality.

The controlled addition of oxygen to the carbon-containing gaseous feedstock enables a control over these processes. The present inventors have discovered that the formation of a graphene layer on the catalyst and catalyst deactivation at temperatures lass than 700° C. can be prevented by reducing the rate of C₂H₂ decomposition by the presence of oxygen. The inventors have also discovered that oxygen absorbed on the surface of catalyst does not diffuse inside the catalyst and is not easily desorbed from the surface of the catalyst. Consequently, the surface of catalyst is quickly covered by oxygen during CNT growth even if low oxygen flow rates are used.

### EXAMPLE

### Effect of Temperature on Yield and Morphology CNTs

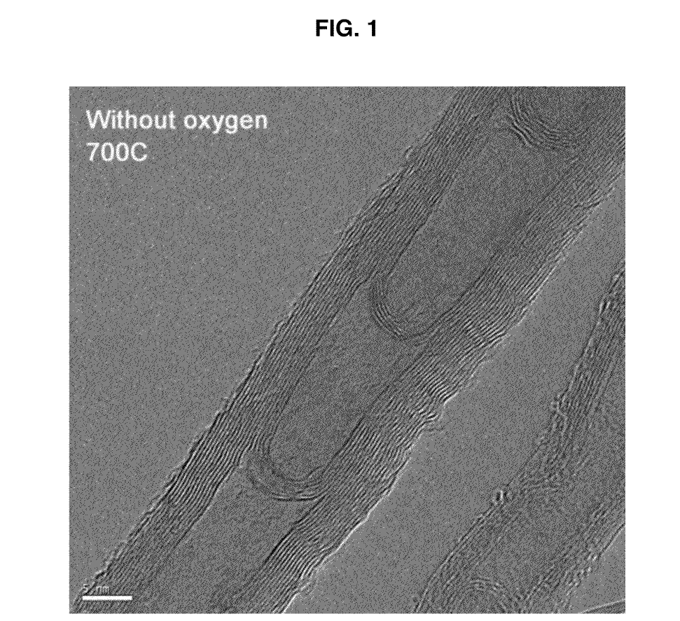

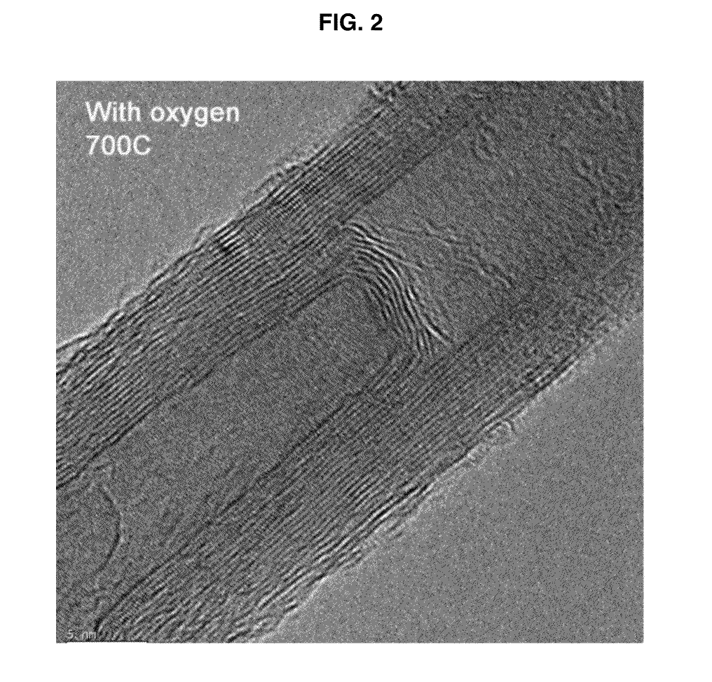

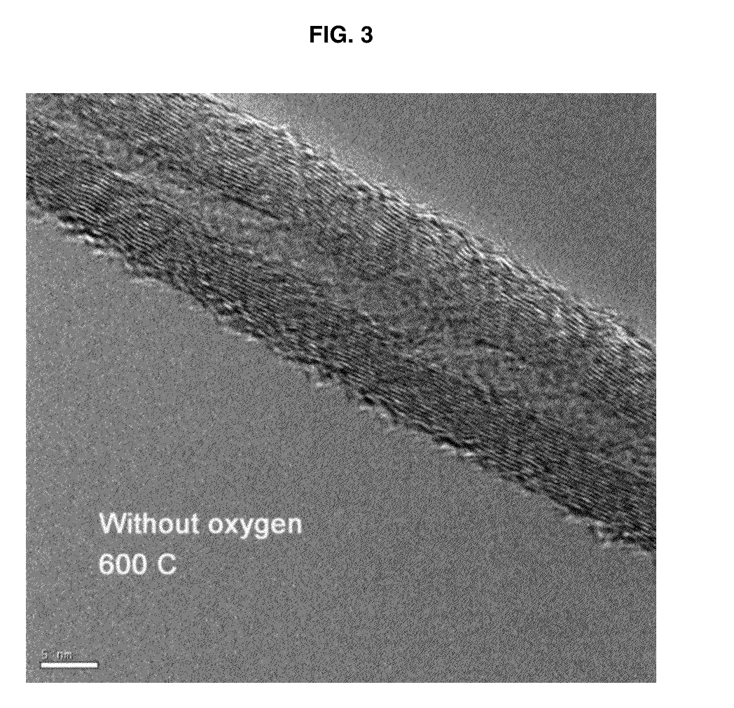

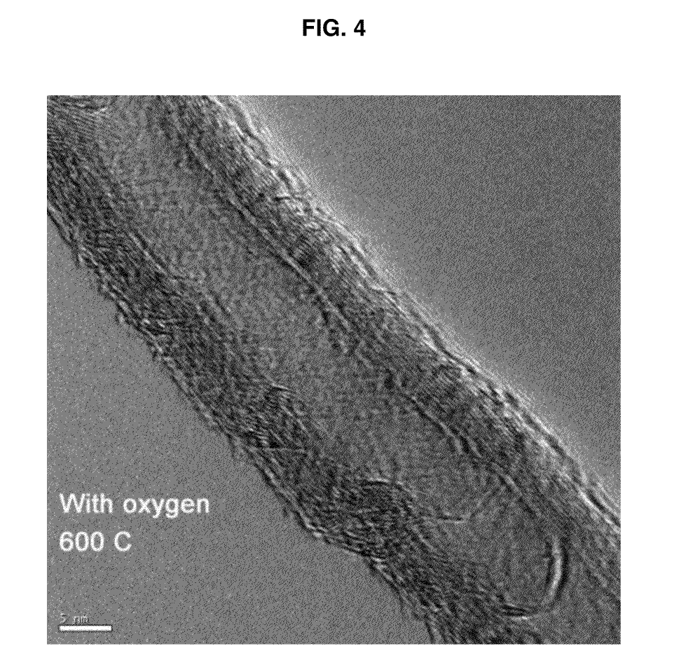

A series of CNT growth experiments were conducted in a Chemical Vapor Deposition Reactor at 2 Torr with an ammonia flow rate of 80 sccm, and acetylene flow rate of 100 sccm, and reactor temperatures ranging from 500° C.-700° C. Yield data and morphology of CNTs were determined for each series of experiments. The morphologies of CNTs grown with 20 sccom oxygen and without oxygen are similar at 700° C., indicating that the presence of oxygen is not detrimental to either the catalytic synthesis process itself or to the internal structure of CNTs (FIGS. 1 and 2). In contrast, synthesis without oxygen at 600° C. produces low-quality CNTs but normal quality CNTs in the presence of oxygen (FIGS. 3 and 4).

While the present invention is described using a limited number of embodiments, it is not intended that the scope of the invention is to be limited to the described embodiments except as set forth in the following claims.

What is claimed is:

1. A method for synthesizing carbon nanotubes inside a chemical vapor deposition chamber and on a substrate comprising the steps of:
a) providing a catalyst for carbon nanotube synthesis distributed on a surface of the substrate in the chemical vapor deposition chamber;
b) providing a supply of gaseous hydrocarbon and a supply of gas comprising oxygen;
c) simultaneously contacting the hydrocarbon and the gas comprising oxygen with the catalyst;
d) heating the hydrocarbons and/or the substrate to a temperature sufficient for carbon nanotube synthesis; and
e) controlling graphene layer formation on the catalyst and catalyst deactivation by varying the contacting of the oxygen with the catalyst.

2. The method of claim 1, wherein the catalyst comprises nanoparticles distributed on a surface of the substrate.

3. The method of claim 1, wherein the catalyst comprises a transition metal.

4. The method of claim 1, wherein the carbon nanotubes on the substrate are aligned.

5. The method of claim 1, wherein the substrate has a melting point of less than about 700° C. and greater than about 600° C.

6. The method of claim 1, wherein the catalyst is selectively heated to a temperature that is higher than the temperature to which the substrate is heated and wherein the melting point of the substrate is between 35° C. and 600° C.

7. The method of claim 1, wherein the substrate is selected from the group consisting of aluminum, polyethylene terephthalate, and polyethylene oxide.

8. The method of claim 1, wherein varying the contacting of oxygen with the catalyst comprises changing a concentration of oxygen in the gas comprising oxygen, changing a rate of flow of the gas comprising oxygen contacting the catalyst, or both.

9. The method of claim 1, wherein the supply of gaseous hydrocarbon and the supply of gas comprising oxygen are the same.

10. The method of claim 1, wherein said heating in step e) comprises heating by a source external to the chemical vapor deposition chamber.

11. A method for preventing the formation of a garphene layer on a catalyst during carbon nanotube synthesis on a catalyst in a chemical vapor deposition chamber at a temperature below 700° C. comprising:
a) providing a substrate comprising the catalyst distributed on a surface of the substrate in the chemical vapor deposition chamber;
b) providing a supply of gaseous hydrocarbon and a supply of gas comprising oxygen;
c) simultaneously contacting the gaseous hydrocarbon and the gas comprising oxygen with the catalyst;
d) heating the gaseous hydrocarbon and/or the catalyst to a temperature of less than 700° C. but sufficient to form carbon nanotubes; and
e) preventing graphene layer formation on the catalyst and catalyst deactivation by varying the contacting of the oxygen with the catalyst.

12. The method of claim 11, wherein the catalyst is in the form of nanoparticles comprising a transition metal distributed on a surface of the substrate.

13. The method of claim 11, wherein the substrate is aluminum and the catalyst is heated to a temperature of between 600° C. and 659° C.

14. The method of claim 11, wherein the carbon nanotubes on a substrate are aligned.

15. The method of claim 11, wherein the melting point of the substrate is less than about 700° C. and greater than 600° C.

16. The method of claim 11, wherein the catalyst is selectively heated to a higher temperature temperature than the substrate and the substrate has a melting point of between 35° C. and 600° C.

17. The method of claim 11, wherein varying the contacting of oxygen with the catalyst comprises changing a concentration of oxygen in the gas comprising oxygen, changing a rate of flow of the gas comprising oxygen contacting the catalyst, or both.

18. A method for synthesizing carbon nanotubes on an aluminum substrate comprising the steps of:
a) providing an aluminum substrate comprising a catalyst distributed on a surface of the aluminum substrate
b) placing the aluminum substrate in a chemical vapor deposition chamber
c) providing a supply of gaseous hydrocarbon and a supply of gas comprising oxygen
d) simultaneously contacting the gaseous hydrocarbon and the gas comprising oxygen with the catalyst; and
e) heating the gaseous hydrocarbon and/or the catalyst to a temperature of less than 660° C. but sufficient to form carbon nanotubes and
f) preventing graphene layer formation on the catalyst and catalyst deactivation by varying the contacting of the oxygen with the catalyst.

19. The method of claim 18, wherein varying the contacting of oxygen with the catalyst comprises changing a concentration of oxygen in the gas comprising oxygen, changing a rate of flow of the gas comprising oxygen contacting the catalyst, or both.

20. The method of claim 18, wherein said heating in step e) comprises heating by a source external to the chemical vapor deposition chamber.
